(19) United States
(12) Patent Application Publication
(10) Pub. No.: US 2024/0047216 A1
(43) Pub. Date: Feb. 8, 2024

(54) Trimming Through Etching in Wafer to Wafer Bonding

(71) Applicant: Taiwan Semiconductor Manufacturing Co., Ltd., Hsinchu (TW)

(72) Inventors: Wei-Ming Wang, Taichung City (TW); Yu-Hung Lin, Taichung City (TW); Shih-Peng Tai, Xinpu Township (TW); Kuo-Chung Yee, Taoyuan City (TW)

(21) Appl. No.: 17/816,782

(22) Filed: Aug. 2, 2022

(51) Int. Cl. H01L 21/308; H01L 21/311; H01L 23/00

(52) U.S. Cl. CPC H01L 21/308; H01L 21/31144; H01L 24/80; H01L 2224/80895; H01L 2224/80896

(57) ABSTRACT

A method includes forming an etching mask over a first wafer. The etching mask covers an inner portion of the first wafer. A wafer edge trimming process is performed to trim an edge portion of the first wafer, with the etching mask protecting the inner portion of the first wafer from being etched. The edge portion forms a full ring encircling the inner portion of the first wafer. The method further includes removing the etching mask, and bonding the first wafer to a second wafer.

### BACKGROUND

Wafer-to-wafer bonding is commonly used in the packaging of integrated circuits. For example, a device wafer having through-vias penetrating through a substrate of the device wafer may be bonded to a carrier wafer or another device wafer. The device wafer may then be thinned, and electrical connectors may be formed on the backside of the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a carrier in accordance with some embodiments.

FIG. 2 illustrates a cross-sectional view of a device wafer in accordance with some embodiments.

FIGS. 3 through 6 illustrate the intermediate stages in a wafer edge trimming process in accordance with some embodiments

FIGS. 7 through 13 illustrate the intermediate stages in a wafer bonding process, with wafers being pre-trimmed, in accordance with some embodiments.

FIGS. 14A and 14B illustrate a cross-sectional view and a top view, respectively, of a wafer-level package in accordance with some embodiments.

FIG. 15 illustrates a cross-sectional view in the sawing of a wafer-level package into die-level packages in accordance with some embodiments.

FIG. 16 illustrates a top view of a wafer that is trimmed using mechanical trimming process.

FIGS. 17 through 22 illustrate the intermediate stages in a wafer bonding process, with wafers being post-trimmed, in accordance with some embodiments.

FIG. 23 illustrates a process flow for a wafer bonding and trimming process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A wafer trimming and bonding process and the formation of a resulting package are provided. In accordance with some embodiments of the present disclosure, a first wafer is bonded to a second wafer. A wafer edge trimming process is performed. The wafer edge trimming process is performed through an etching process, which may be a plasma etching process. By performing the edge trimming process through etching, the trim width is reduced to be smaller than the trim width generated through mechanical trimming process. The wafer edge chipping problem is also avoided. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

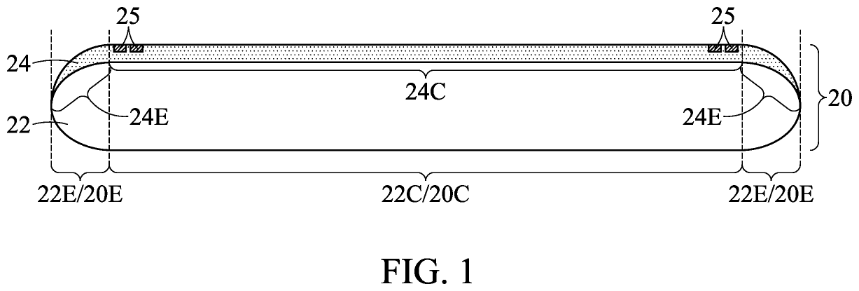

Referring to FIG. 1, wafer 20 is formed. In accordance with some embodiments, wafer 20 is a carrier wafer, and hence is referred to as carrier wafer 20 hereinafter. Carrier wafer 20 may have a round top-view shape. In accordance with some embodiments, carrier wafer 20 includes substrate 22. Substrate 22 may be formed of or comprise silicon, while other materials such as ceramic, glass, silicate glass, or the like, may also be used. In accordance with some embodiments, the entire substrate 22 is formed of a homogeneous material, with no other material different from the homogeneous material therein. For example, the entire substrate 22 may be formed of silicon (doped or undoped), and there are no metal features, dielectric features, etc., therein.

Bond layer 24 is deposited on substrate 22. In accordance with some embodiments, bond layer 24 is formed of or comprises a dielectric material, which may be a silicon-based dielectric material such as silicon oxide (SiO₂), SiN, SiON, SiOCN, SiC, SiCN, or the like, or combinations thereof. In accordance with some embodiments of the present disclosure, bond layer 24 is formed using High-Density Plasma Chemical Vapor Deposition (HDPCVD), Plasma Enhanced Chemical Vapor Deposition (PECVD), Chemical Vapor Deposition (CVD), Low-Pressure Chemical Vapor Deposition (LPCVD), Atomic Layer deposition (ALD), or the like.

In accordance with some embodiments, bond layer 24 is a single layer that is in physical contact with substrate 22. In accordance with alternative embodiments, bond layer 24 is a composite layer including a plurality of layers. For example, bond layer 24 may include an oxide-based layer formed of an oxide-based material (which may also be silicon oxide based) such as silicon oxide, phospho-silicate glass (PSG), borosilicate glass (BSG), boron-doped phospho silicate glass (BPSG), fluorine-doped silicate glass (FSG), or the like. Bond layer 24 may also include a nitride-based layer formed of or comprising silicon nitride, while it may also be formed of or comprise other materials such as silicon oxynitride (SiON). In accordance with some embodiments of the present disclosure, the layers in bond layer 24 may be formed using PECVD, CVD, LPCVD, ALD, or the like.

There may also be alignment marks 25 formed in bond layer 24, which alignment marks 25 are used for aligning wafers in subsequent bonding processes. The alignment marks 25 may be formed as metal plugs, which may be formed through damascene processes.

As shown in FIG. 1, wafer 20 includes edge portion 20E, and inner portion 20C encircled by edge portion 20E. Similarly, substrate 22 includes edge portion 22E, and inner portion 22C encircled by edge portion 22E. Bond layer 24 also includes edge portion 24E, and inner portion 24C encircled by edge portion 24E. When viewed from top, each of edge portions 20E, 22E, and 24E forms a fully ring. In accordance with some embodiments, inner portion 24C of bond layer 24 is conformal and has a uniform thickness. The edge portion 24E, on the other hand, has inner parts closer to inner portion 24C, and outer parts farther away from inner portion 24C than the respective inner portions. The outer parts are increasingly thinner than the respective inner parts.

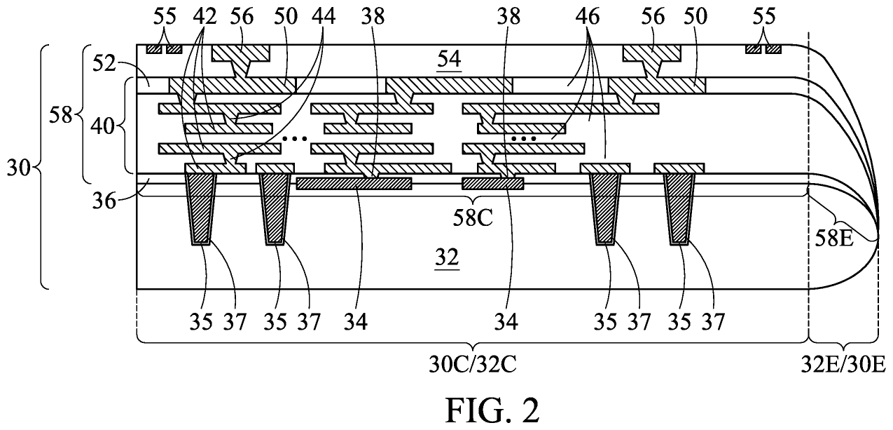

Referring to FIG. 2, device wafer 30 is formed. Device wafer 30 may also have a round top-view shape. In accordance with some embodiments, device wafer 30 includes substrate 32. Substrate 32 may be a semiconductor substrate such as a silicon substrate. In accordance with other embodiments, substrate 32 may include other semiconductor materials such as silicon germanium, carbon-doped silicon or the like. Substrate 32 may be a bulk substrate, or may have a layered structure, for example, including a silicon substrate and a silicon germanium layer over the silicon substrate.

Through-substrate vias 35, which are alternatively referred to as through-vias hereinafter, may be formed to extend from the front side (the illustrated top side) of substrate 32 into substrate 32. The bottoms of through-vias 35 are at a level between the top surface and the bottom surface of substrate 32. Isolation layers 37 are formed to separate through-substrate vias 35 from substrate 32. Isolation layers 37 are formed of a dielectric material. In accordance with alternative embodiments, no through-vias are formed, depending on the function of device wafer 30.

In accordance with some embodiments, device wafer 30 includes a plurality of device dies therein. The illustrated features may be parts of a same device die among a plurality of identical device dies. The device dies may include logic dies, memory dies, input-output dies, Integrated Passive Devices (IPDs), or the like, or combinations thereof. For example, the logic device dies in device wafer 30 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in device wafer 30 may include Static Random-Access Memory (SRAM) dies, Dynamic Random-Access Memory (DRAM) dies, or the like.

In accordance with some embodiments of the present disclosure, integrated circuit devices 34 are formed on the top surface of semiconductor substrate 32. Example integrated circuit devices 34 may include Complementary Metal-Oxide Semiconductor (CMOS) transistors, resistors, capacitors, diodes, and/or the like. The details of integrated circuit devices 34 are not illustrated herein. In accordance with alternative embodiments, device wafer 30 is used for forming interposers, which are free from active devices, and may or may not include passive devices.

Inter-Layer Dielectric (ILD) 36 is formed over semiconductor substrate 32 and fills the space between the gate stacks of transistors (not shown) in integrated circuit devices 34. In accordance with some example embodiments, ILD 36 is formed of or comprises silicon oxide, Phospho Silicate Glass (PSG), Boro Silicate Glass (BSG), Boron-Doped Phospho Silicate Glass (BPSG), Fluorine-Doped Silicate Glass (FSG), or the like. ILD 36 may be formed using spin coating, Flowable Chemical Vapor Deposition (FCVD), Chemical Vapor Deposition (CVD), or the like. In accordance with some embodiments of the present disclosure, ILD 36 is formed using a deposition method such as PECVD, LPCVD, or the like.

Contact plugs 38 are formed in ILD 36, and are used to electrically connect integrated circuit devices 34 to overlying metal lines 42 and vias 44. In accordance with some embodiments of the present disclosure, contact plugs 38 are formed of a conductive material selected from tungsten, aluminum, copper, titanium, tantalum, titanium nitride, tantalum nitride, alloys thereof, and/or multi-layers thereof.

Interconnect structure 40 is formed over ILD 36 and contact plugs 38. Interconnect structure 40 includes metal lines 42 and vias 44, which are formed in dielectric layers 46. Dielectric layers 46 may include Inter-Metal Dielectric (IMD) layers 46 hereinafter. In accordance with some embodiments of the present disclosure, some of dielectric layers 46 are formed of low-k dielectric materials having dielectric constant values (k-values) lower than about 3.5 or 3.0. Dielectric layers 46 may be formed of or comprise a carbon-containing low-k dielectric material, Hydrogen SilsesQuioxane (HSQ), MethylSilsesQuioxane (MSQ), or the like. In accordance with alternative embodiments of the present disclosure, some or all of dielectric layers 46 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, silicon oxynitride, silicon oxycarbide, aluminum oxide, aluminum nitride, or the like, or multi-layers thereof, are formed between dielectric layers 46, and are not shown for simplicity.

Metal lines 42 and vias 44 are formed in dielectric layers 46. The metal lines 42 at a same level are collectively referred to as a metal layer hereinafter. In accordance with some embodiments of the present disclosure, interconnect structure 40 includes a plurality of metal layers that are interconnected through vias 44. Metal lines 42 and vias 44 may be formed of or comprise copper or copper alloys, or other metals. The formation process may include single damascene processes and dual damascene processes.

Dielectric layers 46 may further include passivation layers over the low-k dielectric layers. For example, there may be undoped silicate-glass (USG) layers, silicon oxide layers, silicon nitride layers, etc., over the low-k dielectric layers. The passivation layers are denser than the low-k dielectric layers, and have the function of isolating the low-k dielectric layers from detrimental chemicals and gases such as moisture in external environment.

In accordance with some embodiments, there may be metal pads 50 formed over interconnect structure 40 and electrically connecting to integrated circuit devices 34 through metal lines 42 and vias 44. The metal pads 50 are formed in dielectric layer 52. The metal pads 50 may be formed of or comprises copper, nickel, titanium, palladium, or the like, or alloys thereof. In accordance with some embodiments, metal pads 50 are in a passivation layer 52. In accordance with alternative embodiments, a polymer layer (which may be polyimide, polybenzoxazole (PBO), or the like) may be formed, with the metal pads 50 being in the polymer layer.

Bond layer 54 is deposited as a top surface layer of device wafer 30. Bond layer 54 may be formed of a material selected from the same group of candidate materials for forming bond layer 24. For example, bond layer 54 may be formed of or comprises a material selected from silicon oxide (SiO₂), SiN, SiON, SiOCN, SiC, SiCN, or the like, or combinations thereof. The material of bond layers 24 and 54 may be the same as each other or different from each other. Carrier wafer 30 may include alignment marks 55, which are used for aligning wafers in subsequent bonding processes. Alignment marks 55 may be metal features formed in bond layer 54.

In accordance with some embodiments, wafer 30 is bonded to another wafer through hybrid bonding, and bond pads 56 are formed in bond layer 54. Bond pads 56 have top surfaces that are coplanar with the top surface of bond layer 54. Bond pads 56 may comprise copper, and may also include diffusion barrier layers to separate copper from bond layer 54. In accordance with alternative embodiments, wafer 30 is bonded to another wafer through fusion bonding, and hence no bond pads 56 are formed in bond layer 54.

As also shown in FIG. 2, ILD 36, dielectric layers 46, passivation layer 52, and bond layer 54 are collectively referred to as dielectric layers 58. Similar to wafer wafer 30 includes edge portion 30E forming a ring, and inner portion 30C encircled by edge portion 20E. Substrate 32 includes edge portion 32E, and inner portion 32C encircled by edge portion 32E, and dielectric layers 58 includes inner portion 58C encircled by edge portion 58E. Each of edge portions 30E, 32E, and 58E forms a full ring encircling the respective inner portions 30C, 32C, and 58C. In accordance with some embodiments, inner portion 58C is conformal and has a uniform thickness. The edge portion 58E of dielectric layers 58, on the other hand, has inner parts closer to inner portion 58C, and outer parts farther away from inner portion 58C than the respective inner parts. The outer parts may be increasingly thinner than the respective inner parts.

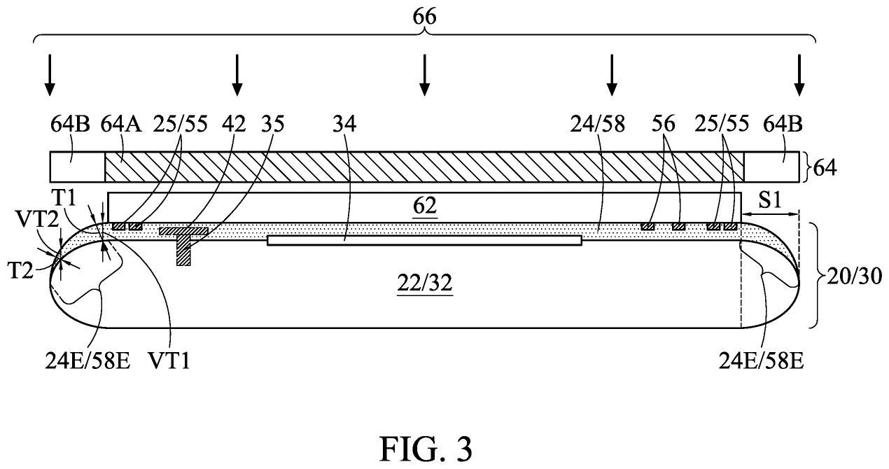

FIGS. 3 through 6 illustrate the cross-sectional views of intermediate stages in a wafer edge trimming process in accordance with some embodiments. Referring to FIG. 3, a wafer is provided, and is denoted as wafer 20/30 to represent that this wafer may be carrier wafer 20 or device wafer 30. The substrate in wafer 20/30 is accordingly denoted as substrate 22/32 to represent that the substrate may be substrate 22 (FIG. 1) or substrate 32 (FIG. 2). The dielectric layers over substrate 22/32 are denoted as 24/58 to represent that these dielectric layers may be bond layer(s) 24 in FIG. 1, or may be dielectric layers 58 in FIG. 2.

In accordance with some embodiments in which wafer 20/30 is device wafer the features as shown in FIG. 2 may be formed, which may include integrated circuit devices 34, through-vias 35, and may or may not include bond pads 56, depending on whether device wafer 30 is to be bonded through hybrid bonding or fusion bonding. In accordance with alternative embodiments in which wafer 20/30 is carrier wafer 20, the features including integrated circuit devices 34, through-vias 35, and bond pads 56 are not formed. Accordingly, in FIG. 3, integrated circuit devices 34, through-vias 35, and bond pads 56 are shown as being dashed to indicate that these features may or may not be formed, depending on whether wafer 20/30 is a carrier wafer or a device wafer.

As further shown in FIG. 3, etching mask 62 is provided. In accordance with some embodiments, etching mask 62 includes a photoresist, and may be a single-layer etching mask (including a photoresist), a double layer etching mask (including a photoresist and a Bottom Anti-Reflective Coating (BARC)), or a tri-layer etching mask (including a top layer, a middle layer, and a bottom layer). In accordance with some embodiments, the formation of the photoresist in etching mask 62 may include spin coating the photoresist, pre-baking the photoresist, performing a light-exposure process 66 on the photoresist, performing a post-baking on the exposed photoresist, and developing the photoresist to remove the edge portions of the photoresist.

The light-exposure process 66 may be performed using lithography mask 64. Lithography mask 64 may include a center round portion 64A and a ring-shaped outer portion 64B encircling the center round portion 64A. One of the center round portion 64A and the ring-shaped outer portion 64B is opaque, and the other is transparent, depending on whether the photoresist is a positive photoresist or a negative photoresist. As a result of the development process, the edge portion of the photoresist in etching mask 62 is removed, leaving the inner portion, as shown in FIG. 3. It is appreciated that at the time the edge portion of the photoresist in etching mask 62 is removed, the lithography mask 64 have already been taken away from above wafer 20/30.

The remaining portion of the photoresist in etching mask 62 covers the entire inner portion of wafer 20/30, and the portions of the photoresist covering the edge portions of wafer 20/30 is removed. In accordance with some embodiments, the uncovered edge portions of wafer 20/30 have no metal features such as metal lines, metal pads, metal alignment marks therein. Accordingly, the remaining etch mask 62 covers the alignment masks 25/55, so that in the subsequent post-trimming process, the alignment marks 55-1 and 55-2 will not act as etching masks to prevent some edge portions of wafer 20/30 from being removed. When etching mask 62 is a double layer or a tri-layer, the layer(s) underlying the photoresist are also etched using the patterned photoresist as an etching mask. When viewed in the top view, the remaining etching mask 62 has a circular shape, and is a blanket layer. In accordance with some embodiments, the lateral distance Si between the edges of etching mask 62 and the respective closest edges of wafer 20/30 may be smaller than about 1 mm, and may be in the range between about 0.5 mm and about 1 mm in accordance with some embodiments.

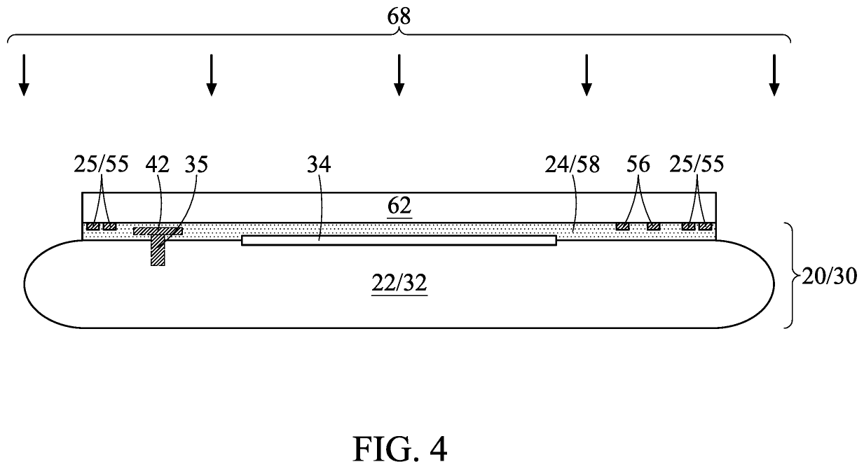

Referring to FIG. 4, edge trimming processes 68 are performed to trim the edge portions of wafer 20/30. In accordance with some embodiments, as shown in FIG. 4, the edge trimming process is performed on wafer 20/30 before it is bonded to another wafer. The corresponding edge trimming process is referred to as a pre-trim process. The edge trimming process is performed through anisotropic etching processes (by applying proper bias power), which may be dry etching processes performed using etching gases. The edge trimming process may also be performed through plasma etching processes.

In accordance with some embodiments, the edge trimming process includes a first etching process(es) to etch dielectric layers 24/58, followed by a second etching process to etch substrate 22/32. The first etching process(es) and the second etching process(es) may be performed in the same etching tool or different etching tools. In accordance with some embodiments, the etching gas of dielectric layers 24/58 may include the mixture of NF₃ and NH₃, the mixture of HF and NH₃, a fluorine-containing gas such as CF₄, NF₃, SF₆, CHF₃, ClF₃, or the like, or combinations thereof. Other gases such as O₂, N₂, H₂, Ar, NO, and the like, may also be added.

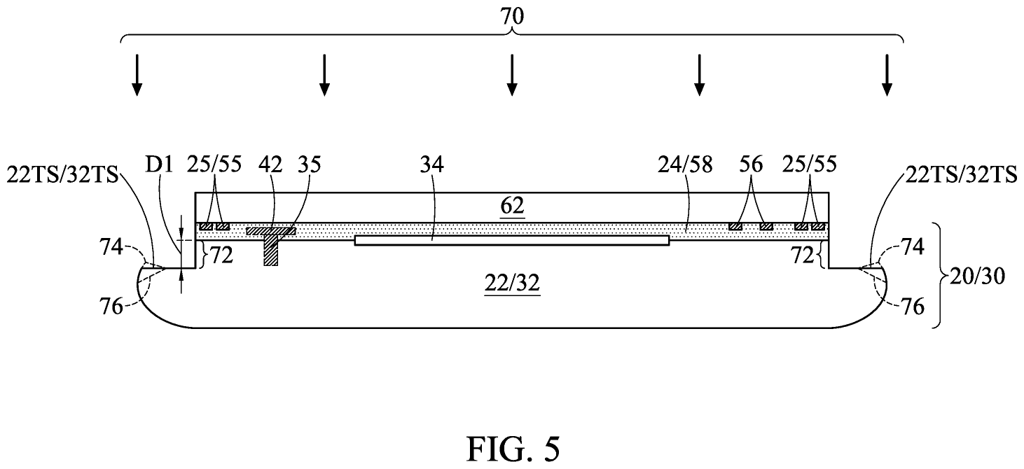

After the etching of dielectric layers 24/58, substrate 22/32 is revealed, and is then etched in etching process 70 (FIG. 5). The resulting wafer 20/30 is illustrated in FIG. 5. The revealed top surface of substrate 32 is thus recessed to form a recess 72, which is a recess ring. It is appreciated that by using etching process to achieve edge trimming, it is easier to control the recessing depth D1. For example, the depth D1 of the recess 72 may be smaller than about 200 and may be greater than 10 μm 20 μm, or 50 The recessing depth D1 may also be smaller than about 100 μm or smaller than about 50 The etching gas of substrate 22/32 may include fluorine (F₂), Chlorine (Cl₂), hydrogen chloride (HCl), hydrogen bromide (HBr), Bromine (Br₂), C₂F₆, CF₄, SO₂, the mixture of HBr, Cl₂, and O₂, or the mixture of HBr, Cl₂, O₂, and CH₂F₂ etc.

The etching processes 68 are controlled to generate recesses 72 with desirable depths and profiles. For example, as shown in FIG. 5, the recessed top surface 22TS/32TS of substrate 22/32 may be planar. This may be achieved by adjusting process conditions such as etching gases and their ratios, wafer temperature, the pressure of etching gases, etc. In accordance with some embodiments, the recessed top surface 22TS/32TS may have the profile shown by dashed line 74. The respective top surface 74 of substrate 22/32 may have a planar inner portion, and a raised outer portion. The raised outer portion may be the result of the difference in the heights (vertical thicknesses) of dielectric layers 24/58. The reasons for forming such profile are discussed as follows.

Referring to FIG. 3, the edge portions 24E/58E of dielectric layers 24/58 have outer portions thinner than the respective inner portions. Thicknesses T2 is thus smaller than thickness T1, wherein both of thicknesses T1 and T2 are measured perpendicular to the respective parts of the surface of substrate 22/32. The heights (vertical thicknesses) of edge portions 24E/58E, however, may not have the same trend. For example, FIG. 3 illustrates two example vertical thicknesses VT1 and VT2, wherein vertical thickness VT2 may be greater than vertical thickness VT1, although thickness T2 is smaller than thickness T1.

Since the etching process 68 is anisotropic, the vertical thicknesses VT1 and VT2, rather than thicknesses T1 and T2, affect which parts of the dielectric layers 24/58 are removed earlier than other. For example, since vertical thickness VT2 may be greater than vertical thickness VT1, when the etching process 68 (FIG. 4) is finished, some inner parts (for example, the part with vertical thickness VT1) of the etched portion 24E/58E are removed, while there may be some outer parts (for example, the part with vertical thickness VT2) remaining. The remaining outer parts of dielectric layers 24/58 thus act as the etching mask for etching substrate 22/32. Accordingly, the starting time for etching some outer parts of substrate 22/32 may be delayed later than the starting time for etching the respective inner parts of substrate 22/32. The delay in the etching of the outer parts of substrate 22/32 causes the top surface 74 as shown in FIG. 5.

In accordance with alternative embodiments, when etching process 70 is started, all of the exposed portions of dielectric layers 24/58 have been removed. Before the substrate 22/32 is etched, the edge part of substrate 22/32 has a rounded end surface. In the etching of substrate 22/32, accordingly, the profile of the rounded end surface is transferred to the recessed top surface of substrate 22/32. The resulting recessed top surface of substrate 22/32 is shown by dashed line 76. The recessed top surface 76 may also include a planar inner portion, and a curved outer portion. The curved outer portion may have the curvature mimic (and may be the same as) the curvature of the un-recessed rounded surface of substrate 22/32 before etching process 70 is started.

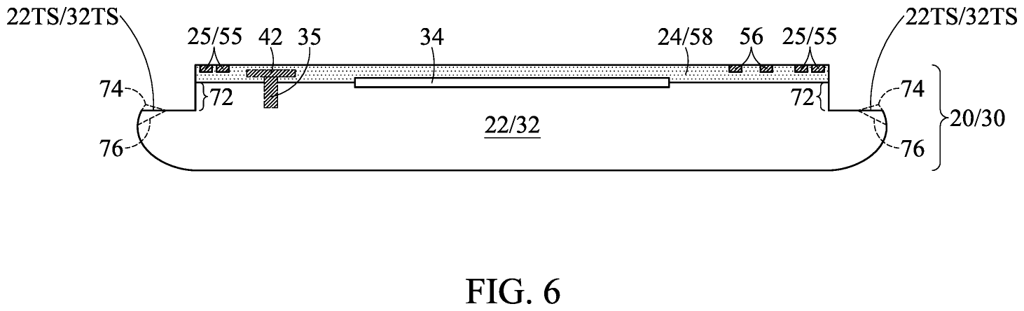

Subsequently, etching mask 62 is removed. The resulting wafer 20/30, which has been pre-trimmed, is shown in FIG. 6.

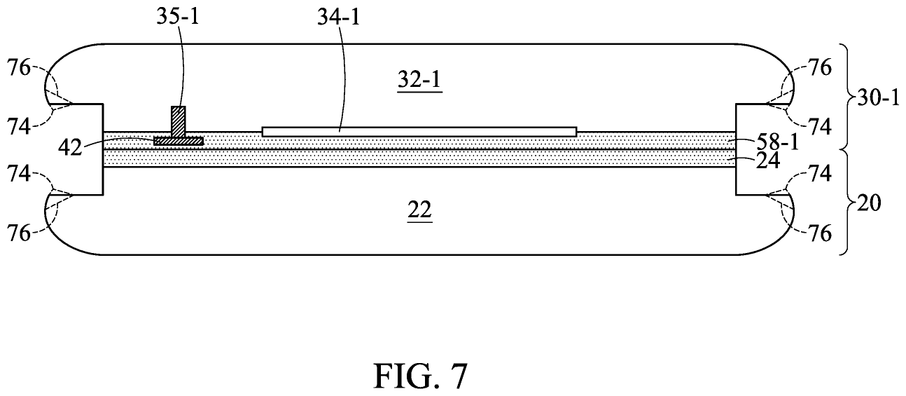

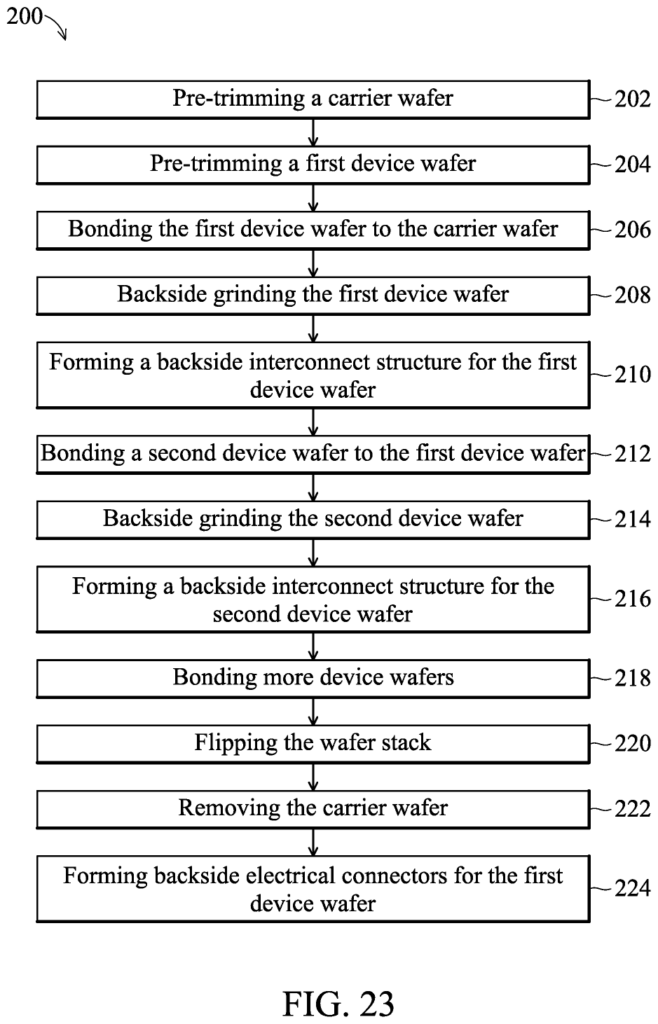

FIGS. 7-13, 14A, 14B, and 15 illustrate the cross-sectional views of intermediate stages in the wafer-to-wafer bonding processes and the formation of the respective packages in accordance with some embodiments. The respective processes are shown in the process flow 200 as shown in FIG. 23. In these processes, pre-trim processes (by using etching processes) are performed on wafers before the wafers are bonded to each other. In the following discussion, device wafers 30 may be identified by following reference number “30” with a “-” sign and a number, which number indicates the tier-number of the respective device wafer. Some of the features in device wafers 30-1 through 30-n may also be distinguished from each other through the tier number. For example, the substrates, the dielectric layers, the bond pads, and the through-vias may be denoted with the corresponding reference numbers as shown in FIG. 2 followed by the corresponding tier numbers.

Referring to FIG. 7, carrier wafer 20 and device wafer 30-1 are formed. It is appreciated that although the illustrated bottom wafer is a carrier wafer in an example embodiment, the bottom wafer may also be a device wafer in accordance with other embodiments. Carrier wafer 20 may be the same as shown in FIG. 1, and device wafer 30-1 may be the same as shown in FIG. 2. Accordingly, the details of the materials, the structures, and the formation processes of carrier wafer 20 and device wafer 30-1 are not repeated herein. Carrier wafer 20 and device wafer 30-1 are pre-trimmed using the processes discussed referring to FIGS. 3 through 6. The respective processes are illustrated as processes 202 and 204 in the process flow 200 as shown in FIG. 23. The details of the pre-trimming processes are thus not repeated herein.

After both of carrier wafer 20 and device wafer 30-1 are pre-trimmed, device wafer 30-1 is bonded to carrier wafer 20, for example, through fusion bonding when wafer 20 is a carrier wafer. The respective process is illustrated as process 206 in the process flow 200 as shown in FIG. 23. In accordance with alternative embodiments in which the bottom wafer is a device wafer, the bonding may be hybrid bonding. In accordance with some embodiments, carrier wafer 20 and device wafer 30-1 are bonded through face-to-face bonding. For example, bond layer 24-1 may be bonded to the surface bond layer (bond layer 54 in FIG. 2) through fusion bonding, wherein Si—O—Si bonds are generated to bond carrier wafer 20 and device wafer 30-1 together.

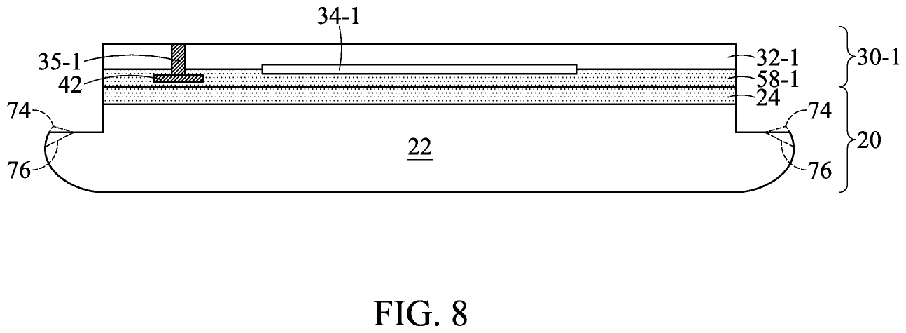

Next, referring to FIG. 8, a backside grinding process is performed to thin the substrate 32-1 in device wafer 30-1. The respective process is illustrated as process 208 in the process flow 200 as shown in FIG. 23. In accordance with some embodiments, the backside grinding process includes a coarse grinding process (for example, through a mechanical grinding process), followed by a fine grinding process (for example, through a Chemical Mechanical Polishing (CMP) process). As a result of the backside grinding process, through-vias 35-1 may be exposed.

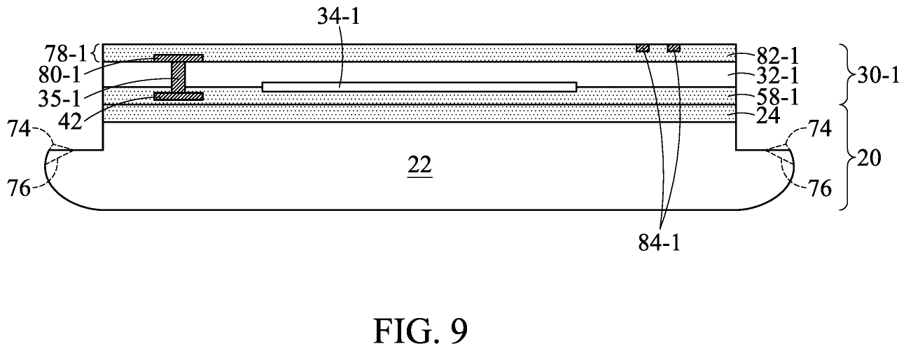

Referring to FIG. 9, backside interconnect structure 78-1 is formed on the backside of substrate 32-1. The respective process is illustrated as process 210 in the process flow 200 as shown in FIG. 23. In accordance with some embodiments, backside interconnect structure 78-1 includes dielectric layers 82-1, and redistribution lines (RDLs) 80-1 in dielectric layers 82-1. A top surface layer of dielectric layers 82-1 may be formed of or comprise a silicon-containing dielectric material such as silicon oxide, silicon nitride, silicon oxynitride, silicon carbide, silicon oxycarbide, or the like. The detailed structure of backside interconnect structure 78-1 is not shown and discussed in detail. RDLs 80-1 are electrically connected to the front-side interconnect structure (such as interconnect structure 40, referring to FIG. 2) through through-vias 35-1. Furthermore, backside interconnect structure 78-1 may include bond pads 84-1, which may have top surfaces coplanar with a top surface of the top surface dielectric layer 82-1. Bond pads 84-1 are electrically and/or signally connected to RDLs 80-1, through-vias 35-1, and integrated circuit devices 34-1.

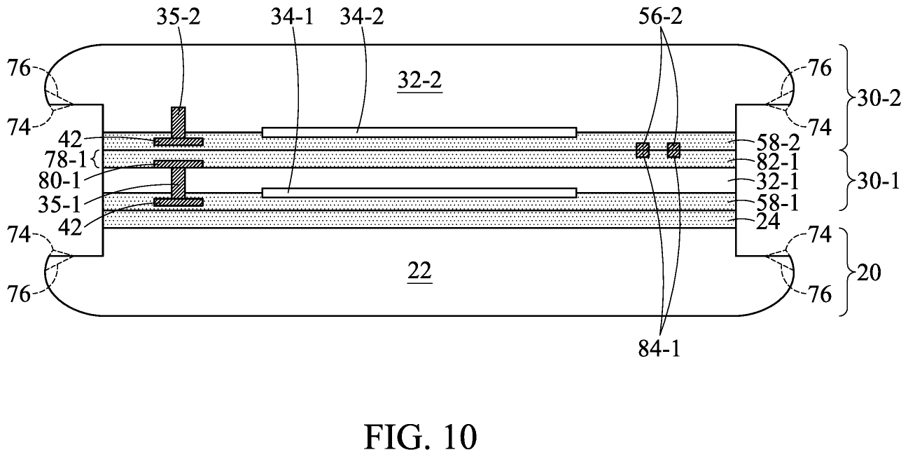

FIG. 10 illustrates the bonding of device wafer 30-2 to device wafer 30-1. The respective process is illustrated as process 212 in the process flow 200 as shown in FIG. 23. Device wafer 30-2 may be the same as or similar to what is shown in FIG. 2, and hence the details of device wafer 20-2 are not discussed in detail. Device wafer is also pre-trimmed using the processes as discussed referring to FIGS. 3 through 6. In accordance with some embodiments, the bonding is performed through hybrid bonding, with a surface dielectric layer (such as 54 in FIG. 2) in dielectric layers 58-2 being bonded to dielectric layer 82-1 in device wafer 30-1 through fusion bonding. Bond pads 56-2 in device wafer 30-2 are also bonded to metal pads 84-1 through direct metal-to-metal bonding. Through bond pads 56-2 and 84, the integrated circuits 34-2 and through-vias 35-2 in device wafer 30-2 are electrically interconnected to the through-vias 35-1 and integrated circuits 34-1 in device wafer 30-1.

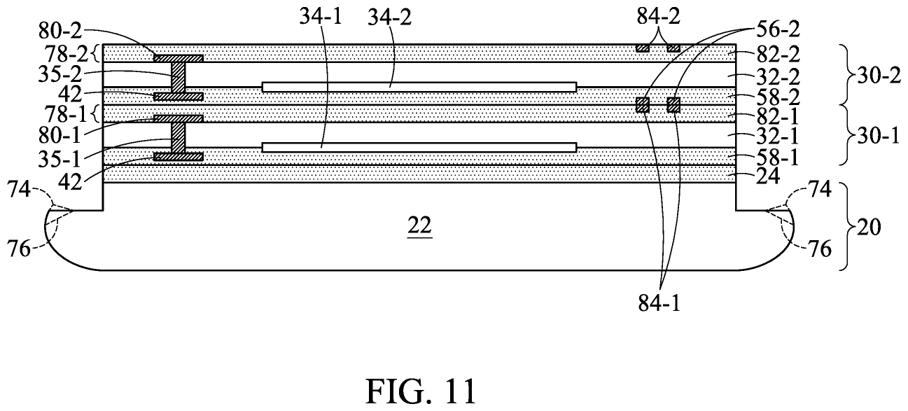

Referring to FIG. 11, a backside grinding process is performed, and through-vias 35-2 are revealed. The respective process is illustrated as process 214 in the process flow 200 as shown in FIG. 23. Next, backside interconnect structure 78-2 is formed, which includes RDLs 80-2, dielectric layers 82-2, and bond pads 84-2. The respective process is illustrated as process 216 in the process flow 200 as shown in FIG. 23. Bond pads 84-2 are electrically and/or signally connected to RDLs 80-2 and through-vias 35-2 and 35-1, and integrated circuit devices 34-2 and 34-1.

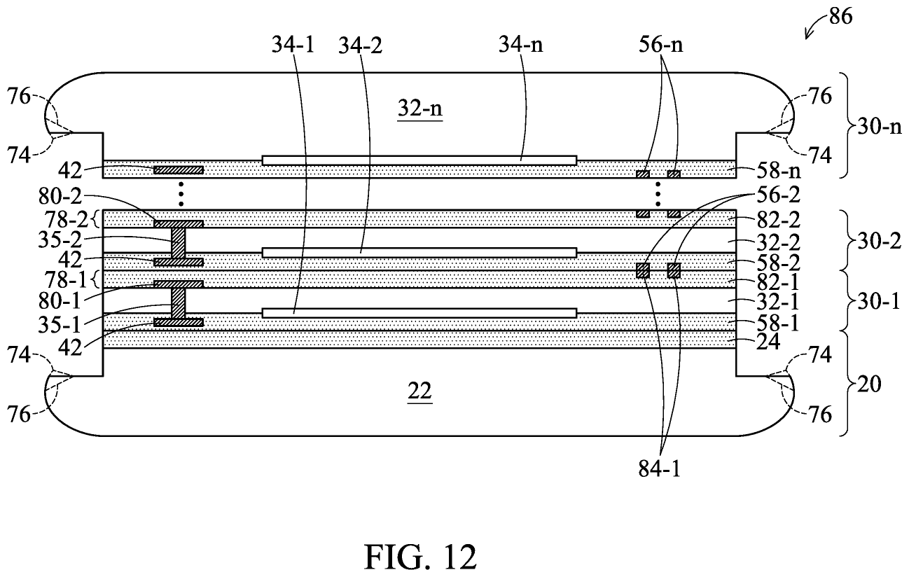

FIG. 12 illustrates the further bonding of more device wafers up to wafer 30-n, wherein integer n may be a number equal to or greater than 3. The respective process is illustrated as process 218 in the process flow 200 as shown in FIG. 23. The resulting stacked wafers are collectively referred to as wafer stack 86. It is appreciated that although wafer stack 86 includes device wafers 30-1 through 30-n as an example, fewer device wafers (such as a single device wafer or two device wafers) may be stacked on carrier wafer in other embodiments. The additional device wafers are also pre-trimmed similar to device wafer 30-2.

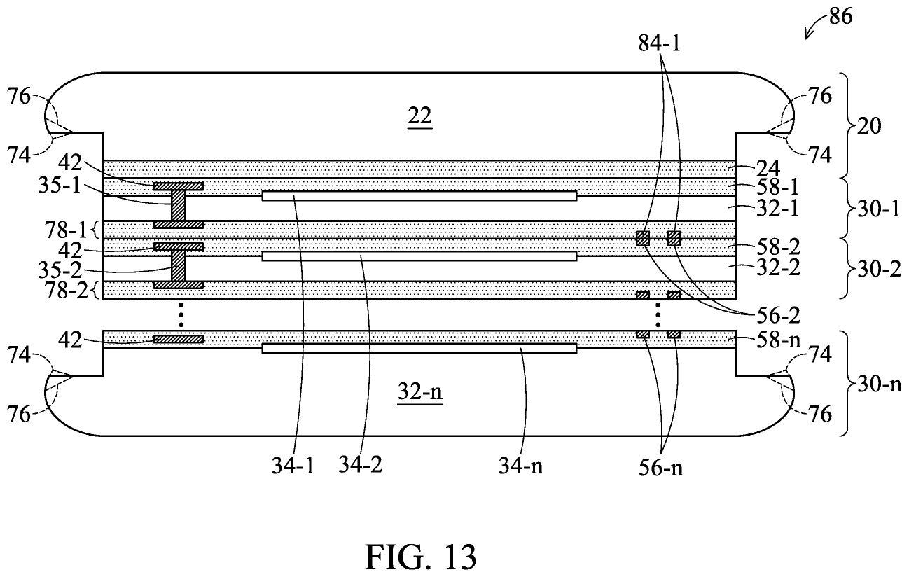

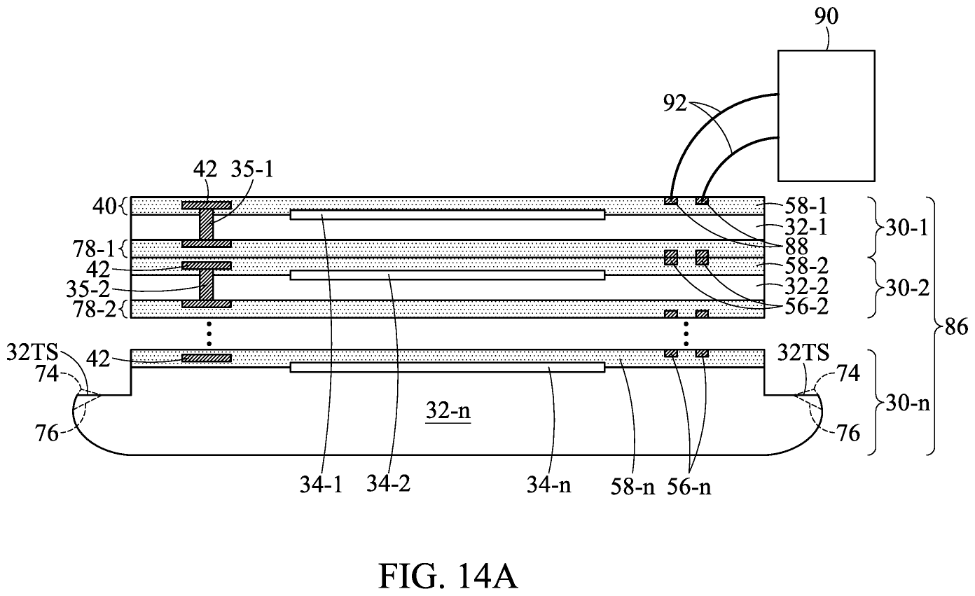

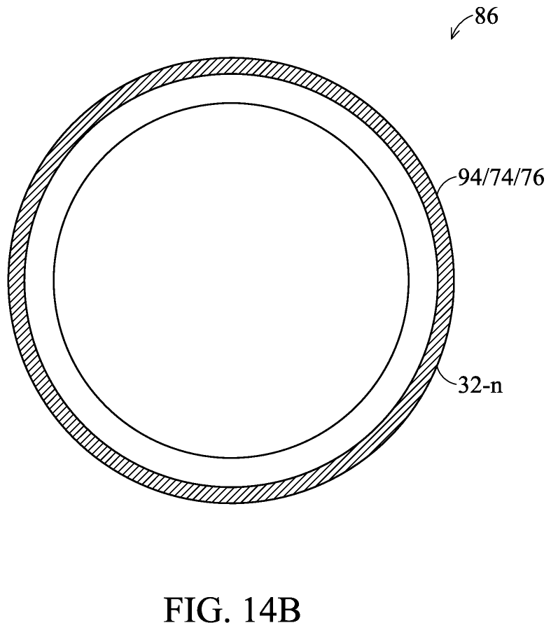

Referring to FIG. 13, wafer stack 86 is flipped upside down, with the backside of carrier wafer 20 facing up. The respective process is illustrated as process 220 in the process flow 200 as shown in FIG. 23. Next, carrier wafer 20 is removed, for example, through a planarization process such as a mechanical grinding process and/or a CMP process. The resulting structure is shown in FIG. 14. The respective process is illustrated as process 222 in the process flow 200 as shown in FIG. 23. Front-side interconnect structure 40 is thus revealed. In a subsequent process, electrical connectors 88 are formed on the top surface of device wafer 30-1. The respective process is illustrated as process 224 in the process flow 200 as shown in FIG. 23. Electrical connectors 88, which are parts of wafer 30-1, are electrically and signally connected to wafers 30-2 through 30-n.

In accordance with some embodiments, wafer stack 86 is used as a whole, without being cut into discrete dies. The edge portions of wafer stack 86 not including devices may be (or may not be) trimmed. For example, FIG. 14A illustrates an example embodiment, wherein wafer stack 86 is connected to package component 90, which may be a printed circuit board, another device die or wafer, a package including device die or wafer therein, or the like. In accordance with some embodiments, wire bonds 92 are formed to electrically connect wafer stack 86 to package component 90. In accordance with other embodiments, other types of electrical connection schemes such as metal-to-metal bonding, solder bonding, or the like may be used.

As shown in FIG. 14A, wafer stack 86 includes substrate 32-n. Substrate 32-n may include a recessed top surface. The recessed top surface may be planar, as shown as top surface 32TS. In accordance with alternative embodiments, the recessed top surface of substrate 32-n may include a planar portion and a raised end portion, as represented by dashed lines 74. In accordance with yet alternative embodiments, the recessed top surface may include a planar portion and a downwardly curved portion, as represented by dashed lines 76. These surfaces may still be present at a time when the wafer stack 86 is used, for example, after final package is performed, and when the wafer stack 86 is powered up.

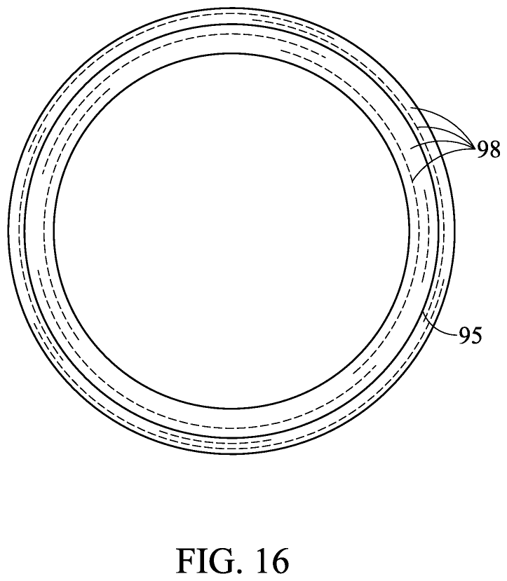

The surface profiles (of the surfaces of substrates) found in the wafer stack 86, which surface profiles are generated due to the wafer trimming through etching, are different from the surface profiles generated using conventional mechanical trimming processes. For example, when mechanical trimming processes are used for wafer edge trimming, the trimmed semiconductor substrate will not have the raised surface 74 and the downwardly curved surface 76. Also, when the wafer edge trimming is performed through mechanical trimming, there will be concentric traces formed on the grinded top surface due to the scratch of the grits on the mechanical wheel. For example, FIG. 16 illustrates a top view of the concentric traces 98. As a comparison, no trace will be generated when etching processes are used for wafer edge trimming, and the recessed top surface of the substrates will be smooth.

In addition, when the wafer edge trimming is performed through mechanical trimming processes, and when the trimmed width is large, for example, greater than about 2 mm, there may be more than one trimming processes performed, each removing a ring portion of the wafer. The top surface of the trimmed substrate will rise slightly in the middle of the ring portions to form a ring-shaped hump. For example, FIG. 16 illustrates a top view of hump 95, which is caused by two trimming processes, one on the inner side of hump 95, and the other on the outer side of hump 95. In the embodiments of the present disclosure, when etching processes are used for wafer edge trimming, no hump will be generated.

FIG. 14B illustrates a top view of wafer stack 86 as shown in FIG. 14A. The substrate 32-n has an outer portion 94 forming a ring, whose top surface may be the raised outer portion of the top surface 74 as shown in FIG. 14A, or the downward curved portion of the top surface 76 as shown in FIG. 14A.

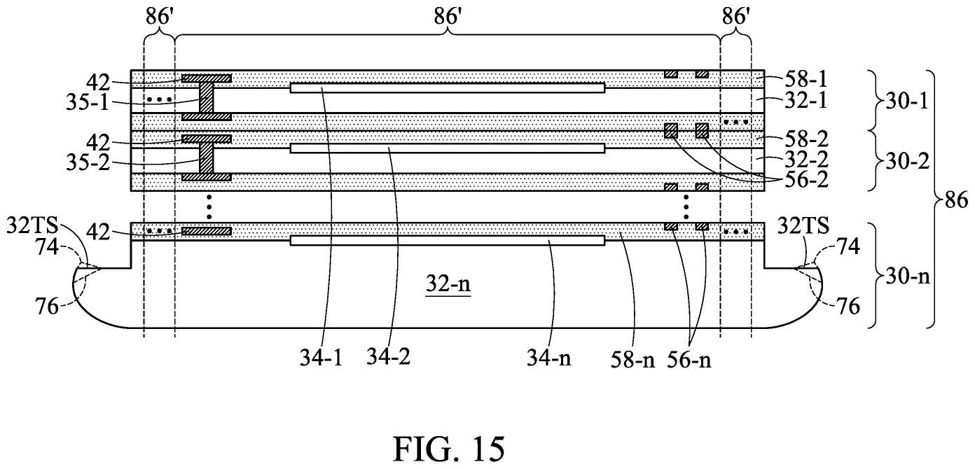

FIGS. 14A and 14B illustrate the embodiments in which wafer stack 86 is used as a wafer-level package, and is not singulated as discrete packages. FIG. 15 illustrates an embodiment in which wafer stack 86 is singulated in sawing processes, so that a plurality of packages 86′ are generated. Packages 86′ are identical to each other, with each including the features as discussed.

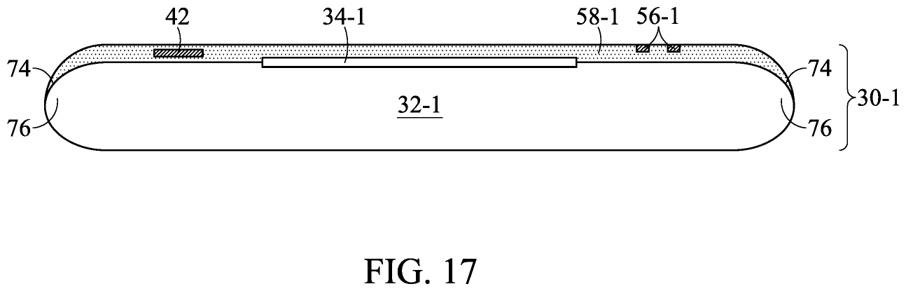

FIGS. 17 through 22 illustrate the cross-sectional views of intermediate stages in the formation of a wafer or a singulated package in accordance with alternative embodiments of the present disclosure. These embodiments are similar to the previously discussed embodiments, except pre-trim processes are used in the preceding embodiments, while post-trim processes are used in the embodiments shown in FIGS. 17 through 22. Unless specified otherwise, the materials and the formation processes of the components in these embodiments are essentially the same as the like components denoted by like reference numerals in the preceding embodiments shown in FIGS. 1-13, 14A, 14B, and 15. The details regarding the formation process and the materials of the components shown in FIGS. 17 through 22 may thus be found in the discussion of the preceding embodiments.

Referring to FIG. 17, device wafer 30-1 is provided. The details of device wafer 30-1 may be found referring to the discussion of FIG. 2, and hence are not repeated herein. The device wafers and the corresponding features in the device wafers may also be distinguished from each other by their tier numbers. In accordance with some embodiments, device wafer 30-1 does not include through-vias extending into substrate 32-1. In accordance with alternative embodiments, device wafer 30-1 also includes through-vias extending into substrate 32-1, depending on whether there will be more device wafer bonded to the bottom side of substrate 32-1.

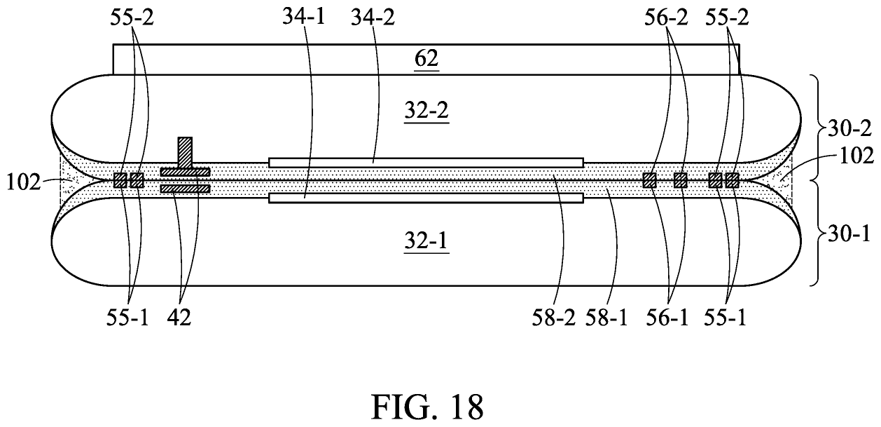

Next, as shown in FIG. 18, device wafer 30-2 is bonded to device wafer 30-1, for example, through hybrid bonding. The bonding may also be achieved through a face-to-face bonding process. The bond pads 56-1 in device wafer 30-1 are bonded with the bond pads 56-2, so that the integrated circuits 34-1 in device wafer 30-1 and integrated circuits 34-2 in device wafer 30-2 are electrically and signally interconnected.

In accordance with some embodiments, protection layer 102 is dispensed into the gap between device wafers 30-1 and 30-2, and on the sidewalls of interconnect structures 40-1 and 40-2. In accordance with some embodiments, protection layer 102 is formed of or comprises a polymer such as polyimide, PBO, or the like. In accordance with alternative embodiments, protection layer 102 is formed of or comprises an inorganic material such as an oxide. Protection layer 102 may be dispensed in a flowable form, and is then cured and solidified. Furthermore, protection layer 102 is dispensed as a full ring when viewed from top. In accordance with alternative embodiments, the formation of protection layer 102 is skipped. Accordingly, protection layer 102 is shown as being dashed to indicate that it may or may not be formed.

Next, as also shown in FIG. 18, etching mask 62 is formed to cover the inner portion of device wafer 30-2, while a ring-shaped edge portion of device wafer 30-2 is not covered. Etching mask 62 may include a photoresist. Etching mask 62 covers the alignment marks 55-1 in device wafer 30-1 and alignment marks 55-2 in device wafer so that in the subsequent post-trimming process, the alignment marks 55-1 and will not act as parts of etching masks. Also, the edge portions of device wafers 30-1 and 30-2 not covered by etching mask 62 are also free from metal features.

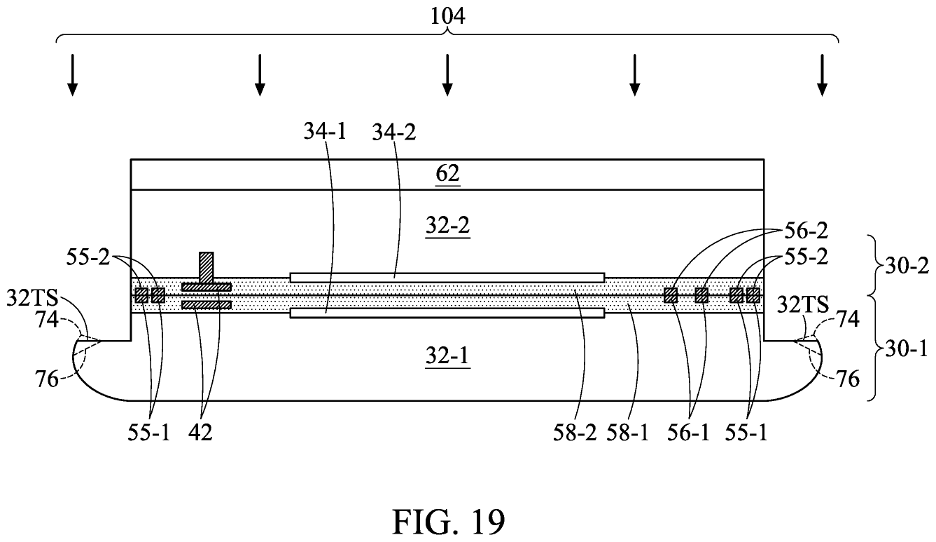

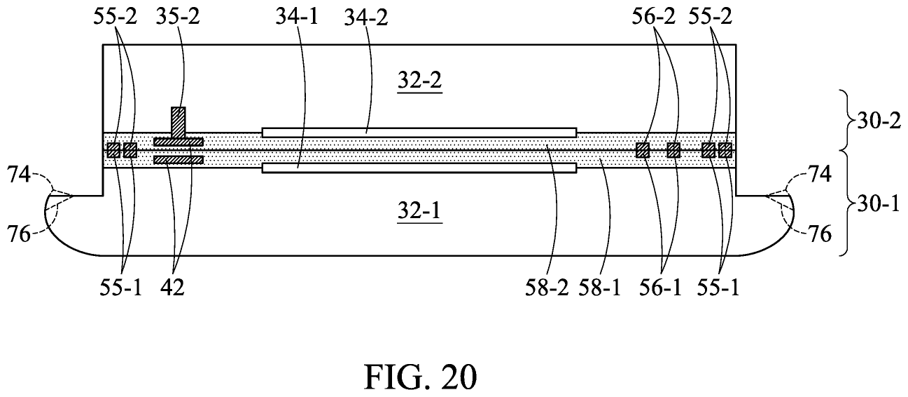

Referring to FIG. 19, etching processes 104, which are anisotropic, are performed to post-trim device wafers 30-2 and 30-1. In the etching processes, substrate 32-2, dielectric layers 58-2, dielectric layers 58-1, protection layer 102, and substrate 32-1 are sequentially etched. The dielectric layers 58-2, dielectric layers 58-1, and protection layer 102 may be etched in a same etching process, which is a different etching process than the etching of substrates 32-2 and 32-1. In accordance with some embodiments, the resulting top surface of the recessed portion of substrate 32-1 may be planar, raised at end (and having a planar inner portion), or downwardly curved at the end (and also having a planar inner portion), as represented by the solid planar top surface 32TS and dashed lines 74 and 76. Etching mask 62 is then removed, and the resulting structure is shown in FIG. 20.

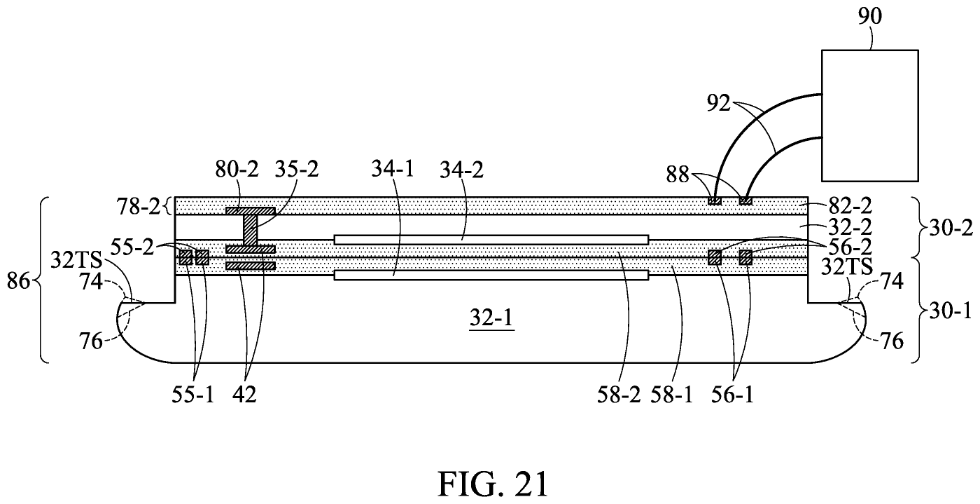

In a subsequent process, as shown in FIG. 21, substrate 32-2 is thinned to reveal through-vias 35-2. Backside interconnect structure 78-2 is then formed, which may include dielectric layers 82-2 and RDLs 80-2 therein. Electrical connectors 88 are also formed on the top surface of the resulting wafer stack 86. Electrical connectors 88, which are parts of wafer 30-2, are electrically and signally connected to device wafer and 30-2. Wafer stack 86 is thus formed.

In accordance with some embodiments, wafer stack 86 is used as a whole, without being cut into discrete packages. For example, FIG. 21 illustrates an example embodiment, wherein wafer stack 86 is connected to package component 90, which may be a printed circuit board, or another package including a device die(s) or a wafer therein. In accordance with some embodiments, wire bonds 92 are formed to electrically connect wafer stack 86 to package component 90. In accordance with other embodiments, other types of electrical connection schemes such as metal-to-metal bonding, solder bonding, or the like may be used. The structure of wafer stack 86 as observed in FIG. 21 may also be present in a final package in which wafer stack 86 is powered up and used. The top view of wafer stack 86 may be similar to what is shown in FIG. 14B, and the raised portion or the downward curved portion of the recessed surface of substrate 32-1 may form a full ring.

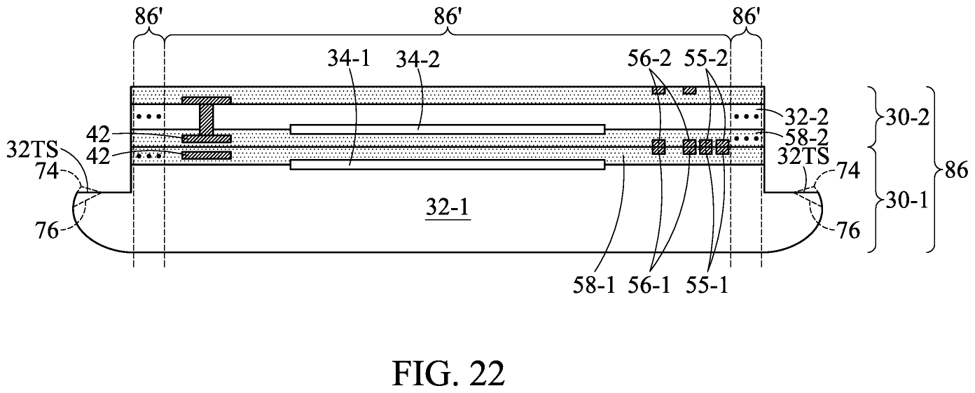

FIG. 22 illustrates an embodiment in which wafer stack 86 is singulated in sawing processes, so that a plurality of packages 86′ are generated. Package 86′ are identical to each other, with each including the features as discussed.

The embodiments of the present disclosure have some advantageous features. By performing wafer edge trimming processes through etching processes rather than through mechanical trimming processes using trim wheels, the trimmed portions of the wafers may be narrower. Also, when using trimming wheels to perform the trimming processes, wafer chipping may be resulted. By adopting etching processes to achieve wafer edge trimming processes, the chipping on the wafer edges is also avoided since no mechanical force is applied.

In accordance with some embodiments of the present disclosure, a method comprises forming an etching mask over a first wafer, wherein the etching mask covers an inner portion of the first wafer; performing a wafer edge trimming process to trim an edge portion of the first wafer, with the etching mask protecting the inner portion of the first wafer from being etched, wherein the edge portion forms a full ring encircling the inner portion; removing the etching mask; and bonding the first wafer to a second wafer. In an embodiment, the edge portion has a width smaller than about 1 mm. In an embodiment, the first wafer comprises a semiconductor substrate, and a plurality of dielectric layers over the semiconductor substrate, and wherein in the wafer edge trimming process, the plurality of dielectric layers are etched-through, and wherein a top surface portion of the semiconductor substrate is etched.

In an embodiment, after the wafer edge trimming process, a lower portion of the semiconductor substrate directly underlying the top surface portion has a top surface, and wherein the top surface is planar. In an embodiment, after the wafer edge trimming process, a lower portion of the semiconductor substrate directly underlying the top surface portion has a top surface, and the top surface comprises a planar inner portion, and a raised portion on an outer side of the planar inner portion. In an embodiment, after the wafer edge trimming process, a lower portion of the semiconductor substrate directly underlying the top surface portion has a top surface, and the top surface comprises a planar inner portion, and a downward curved portion on an outer side of the planar inner portion.

In an embodiment, the wafer edge trimming process is performed before the first wafer is bonded to the second wafer. In an embodiment, the wafer edge trimming process is performed after the first wafer is bonded to the second wafer, and wherein in the wafer edge trimming process, both of the second wafer and the first wafer are trimmed. In an embodiment, the method further comprises, before the first wafer is bonded to the second wafer, performing an additional wafer edge trimming process on the second wafer, and wherein the method further comprises, after the first wafer is bonded to the second wafer, thinning the second wafer. In an embodiment, the method further comprises bonding a third wafer to the second wafer that has been thinned. In an embodiment, the first wafer is a carrier wafer, and the second wafer is a device wafer. In an embodiment, both of the first wafer and the second wafer are device wafers.

In accordance with some embodiments of the present disclosure, a method comprises applying a photoresist over a first wafer, wherein the first wafer has a round top-view shape, and the first wafer comprises a semiconductor substrate and at least one dielectric layer over the semiconductor substrate; performing a lithography process to pattern the photoresist, so that the photoresist covers a round inner portion of the first wafer; performing a first etching process to etch the at least one dielectric layer in an edge portion of the first wafer, so that a first top surface of the semiconductor substrate is exposed; performing a second etching process to etch the semiconductor substrate in the edge portion of the first wafer, so that the semiconductor substrate is recessed to have a second top surface lower than the first top surface; and removing the photoresist.

In an embodiment, the first wafer comprises a plurality of bond pads in a top dielectric layer in the at least one dielectric layer, and the photoresist covers the plurality of bond pads, and wherein the etched edge portion of the first wafer is free from metal features therein. In an embodiment, the method further comprises bonding a second wafer to the first wafer through wafer-to-wafer bonding. In an embodiment, the photoresist is further over the second wafer, and wherein the method further comprises, before the first etching process, performing a third etching process using the photoresist as an etching mask, and wherein the second wafer is etched-through.

In accordance with some embodiments of the present disclosure, a method comprises forming a first plurality of dielectric layers over a first semiconductor substrate to form a first wafer; etching a first edge portion of the first wafer to etch-through the first plurality of dielectric layers and to recess the first semiconductor substrate, wherein the first edge portion of the first wafer has a ring shape; and bonding a second wafer to the first wafer. In an embodiment, the method further comprises etching a second edge portion of the second wafer to etch-through a second plurality of dielectric layers and a second semiconductor substrate in the second wafer. In an embodiment, the second wafer is etched after the second wafer is bonded to the first wafer. In an embodiment, the second wafer is etched before the second wafer is bonded to the first wafer, and the method further comprises thinning the second wafer to reveal a through-via in the second semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an etching mask over a first wafer, wherein the etching mask covers an inner portion of the first wafer;
performing a wafer edge trimming process to trim an edge portion of the first wafer, with the etching mask protecting the inner portion of the first wafer from being etched, wherein the edge portion forms a full ring encircling the inner portion;
removing the etching mask; and
bonding the first wafer to a second wafer.

2. The method of claim 1, wherein the edge portion has a width smaller than about 1 mm.

3. The method of claim 1, wherein the first wafer comprises a semiconductor substrate, and a plurality of dielectric layers over the semiconductor substrate, and wherein in the wafer edge trimming process, the plurality of dielectric layers are etched-through, and wherein a top surface portion of the semiconductor substrate is etched.

4. The method of claim 3, wherein after the wafer edge trimming process, a lower portion of the semiconductor substrate directly underlying the top surface portion has a top surface, and wherein the top surface is planar.

5. The method of claim 3, wherein after the wafer edge trimming process, a lower portion of the semiconductor substrate directly underlying the top surface portion has a top surface, and the top surface comprises a planar inner portion, and a raised portion on an outer side of the planar inner portion.

6. The method of claim 3, wherein after the wafer edge trimming process, a lower portion of the semiconductor substrate directly underlying the top surface portion has a top surface, and the top surface comprises a planar inner portion, and a downward curved portion on an outer side of the planar inner portion.

7. The method of claim 1, wherein the wafer edge trimming process is performed before the first wafer is bonded to the second wafer.

8. The method of claim 1, wherein the wafer edge trimming process is performed after the first wafer is bonded to the second wafer, and wherein in the wafer edge trimming process, both of the second wafer and the first wafer are trimmed.

9. The method of claim 1 further comprising, before the first wafer is bonded to the second wafer, performing an additional wafer edge trimming process on the second wafer, and wherein the method further comprises, after the first wafer is bonded to the second wafer, thinning the second wafer.

10. The method of claim 9 further comprising bonding a third wafer to the second wafer that has been thinned.

11. The method of claim 1, wherein the first wafer is a carrier wafer, and the second wafer is a device wafer.

12. The method of claim 1, wherein both of the first wafer and the second wafer are device wafers.

13. A method comprising:
applying a photoresist over a first wafer, wherein the first wafer has a round top-view shape, and the first wafer comprises a semiconductor substrate and at least one dielectric layer over the semiconductor substrate;
performing a lithography process to pattern the photoresist, so that the photoresist covers a round inner portion of the first wafer;
performing a first etching process to etch the at least one dielectric layer in an edge portion of the first wafer, so that a first top surface of the semiconductor substrate is exposed;
performing a second etching process to etch the semiconductor substrate in the edge portion of the first wafer, so that the semiconductor substrate is recessed to have a second top surface lower than the first top surface; and
removing the photoresist.

14. The method of claim 13, wherein the first wafer comprises a plurality of bond pads in a top dielectric layer in the at least one dielectric layer, and the photoresist covers the plurality of bond pads, and wherein the edge portion of the first wafer is free from metal features therein.

15. The method of claim 13 further comprising bonding a second wafer to the first wafer through wafer-to-wafer bonding.

16. The method of claim 15, wherein the photoresist is further over the second wafer, and wherein the method further comprises, before the first etching process, performing a third etching process using the photoresist as an etching mask, and wherein the second wafer is etched-through.

17. A method comprising:
forming a first plurality of dielectric layers over a first semiconductor substrate to form a first wafer;
etching a first edge portion of the first wafer to etch-through the first plurality of dielectric layers and to recess the first semiconductor substrate, wherein the first edge portion of the first wafer has a ring shape; and
bonding a second wafer to the first wafer.

18. The method of claim 17 further comprising:
etching a second edge portion of the second wafer to etch-through a second plurality of dielectric layers and a second semiconductor substrate in the second wafer.

19. The method of claim 18, wherein the second wafer is etched before the second wafer is bonded to the first wafer, and the method further comprises thinning the second wafer to reveal a through-via in the second semiconductor substrate.

20. The method of claim 17, wherein the second wafer is etched after the second wafer is bonded to the first wafer.
